(19) United States
(12) Patent Application Publication
(10) Pub. No.: US 2025/0131955 A1
(43) Pub. Date: Apr. 24, 2025

(54) APPARATUSES AND METHODS FOR ROW HAMMER COUNTER INITIALIZATION

(71) Applicant: Micron Technology, Inc., Boise, ID (US)

(72) Inventors: Yuan He, Boise, ID (US); Wenlun Zhang, Chofu (JP)

(73) Assignee: Micron Technology, Inc., Boise, ID (US)

(21) Appl. No.: 18/756,919

(22) Filed: Jun. 27, 2024

Related U.S. Application Data
(60) Provisional application No. 63/591,685, filed on Oct. 19, 2023.

(51) Int. Cl. G11C 11/4072; G11C 11/4078; G11C 11/4091

(52) U.S. Cl. CPC G11C 11/4072; G11C 11/4078; G11C 11/4091

(57) ABSTRACT

Embodiments of the disclosure are drawn to apparatuses and methods for row hammer counter resets. Repeated access to an aggressor word line may cause increased data degradation in nearby victim word lines of the memory. The access count value of a given word line may be stored in counter memory cells positioned along that word line. The count values may be randomly or pseudo-randomly initialized. In some examples, a memory device may utilize residual charges that are present on the counter cells during start-up to initialize the counter memory cells. In some other examples, a memory device may utilize threshold voltage compensation (VtC) settings at start-up to initialize the counter memory cells. In some other examples, a memory device may utilize a combination of the residual charges that are present on the counter cells and VtC settings on start-up to initialize the counter memory cells.

### CROSS-REFERENCE TO RELATED APPLICATIONS

This application claims the filing benefit of U.S. Provisional Application No. 63/591,685, filed Oct. 19, 2023. This application is incorporated by reference herein in its entirety and for all purposes.

### BACKGROUND

Information may be stored on individual memory cells of the memory as a physical signal (e.g., a charge on a capacitive element). The memory may be a volatile memory, and the physical signal may decay over time (which may degrade or destroy the information stored in the memory cells). It may be necessary to periodically refresh the information in the memory cells by, for example, rewriting the information to restore the physical signal to an initial value.

As memory components have decreased in size, the density of memory cells has greatly increased. Repeated access to a particular memory cell or group of memory cells (often referred to as a ‘row hammer’) may cause an increased rate of data degradation in nearby memory cells.

### BRIEF DESCRIPTION OF THE DRAWINGS

FIG. 1 is a block diagram of a semiconductor device according to an embodiment of the present disclosure.

FIG. 2 is a block diagram of a memory cell array according to an embodiment of the present disclosure.

FIG. 3 is a block diagram of a refresh address control circuit according to an embodiment of the present disclosure.

FIG. 4 is a schematic diagram of a memory system according to an embodiment of the present disclosure.

FIG. 5 is a schematic diagram of a memory system according to an embodiment of the present disclosure.

FIGS. 6a and 6b are timing diagrams according to an embodiment of the present disclosure.

FIG. 7 is a block diagram of a sense amplifier threshold voltage compensation pulse width system according to an embodiment of the present disclosure.

FIG. 8 is a schematic diagram of a sense amplifier according to an embodiment of the present disclosure.

FIG. 9 is a timing diagram according to an embodiment of the present disclosure.

FIGS. 10a, 10b, and 10c are timing diagrams according to an embodiment of the present disclosure.

FIG. 11 is a memory system according to an embodiment of the present disclosure.

FIGS. 12a-12c are flowcharts depicting methods of initializing counter memory cells according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a volatile memory device may be stored in memory cells (e.g., as a charge on a capacitive element), and may decay over time. The memory cells may be organized into rows (word lines) and columns (bit lines), and the memory cells may be accessed on a row-by-row basis. The memory cells may also be periodically refreshed on a row-by-row basis as part of an auto-refresh operation, where the information along the row is restored to prevent data loss due to the decay over time (e.g., the memory cells may be restored to an initial charge value associated with the logical level stored in that memory cell). Repeated access to a particular row of memory (e.g., an aggressor row) may cause an increased rate of decay in neighboring rows (e.g., victim rows) due, for example, to electromagnetic coupling between the rows. The victim rows may decay faster than the timing of the auto-refresh operation. In order to prevent information from being lost, it may be desirable to identify aggressor rows so that the corresponding victim rows can be refreshed as part of a targeted refresh operation.

Aggressor rows may be determined based on one or more of a number of accesses to the row, the rate of accesses to the row, and/or the length of time over which the row is accessed. In order to prevent row hammer effects from being missed, it may be desirable to track accesses to each row of a memory device.

Some techniques exist for managing row access counts. Each row of the memory may include a number of memory cells which hold an access count of the row they are located on. These memory cells may generally be referred to as counter memory cells. In some embodiments of the disclosure, the counter memory cells are additional memory cells to the memory cells in the row of memory. In some embodiments of the disclosure, the counter memory cells are included in the memory cells of the row of memory. The individual counter memory cells for a given row may store bits that, when taken together, represent an access count for that row. When the row is accessed, the counter memory cells may be read to a counter circuit. The counter circuit may check a value of the count. If the value of the count is below (or equal to) a threshold, the value of the count may be changed (e.g., incremented), and the changed value may be written back to the counter memory cells of the accessed row. If the value of the count is above the threshold value, a control signal may be provided which indicates that the currently accessed row is an aggressor row. The value of the count may then be reset, and the reset value written back to the counter memory cells. Based on the control signal, the memory device may determine the positions of one or more victim rows associated with the aggressor row (e.g., the currently accessed row), and perform a targeted refresh on the victim rows (and/or queue up the aggressor row for a later targeted refresh operation). By storing an access count on the row with which the access count is associated, it may be possible to achieve increased reliability and/or speed of access tracking.

However, in some scenarios, the value of the count may be able to be known. For example, on computer start-up, the value of the count may be initialized as zero since no accesses to any rows have occurred yet. If the threshold is known, one may be able to keep track of the counts of rows to cause damage to the rows. For example, a malicious user may be able to continuously generate queue overflow by activating multiple rows in turn, causing a performance drop of the memory system.

The present disclosure is drawn to apparatuses, systems, and methods for initializing the counter memory cells with random or pseudo-random count values. In some examples, a memory device may utilize the initial charges (e.g., residual charges) that are present on the counter cells during start-up to initialize the counter memory cells. In some other examples, a memory device may utilize threshold voltage compensation (VtC) settings at start-up to initialize the counter memory cells. In some other examples, a memory device may utilize a combination of the initial charges that are present on the counter cells and VtC settings on start-up to initialize the counter memory cells.

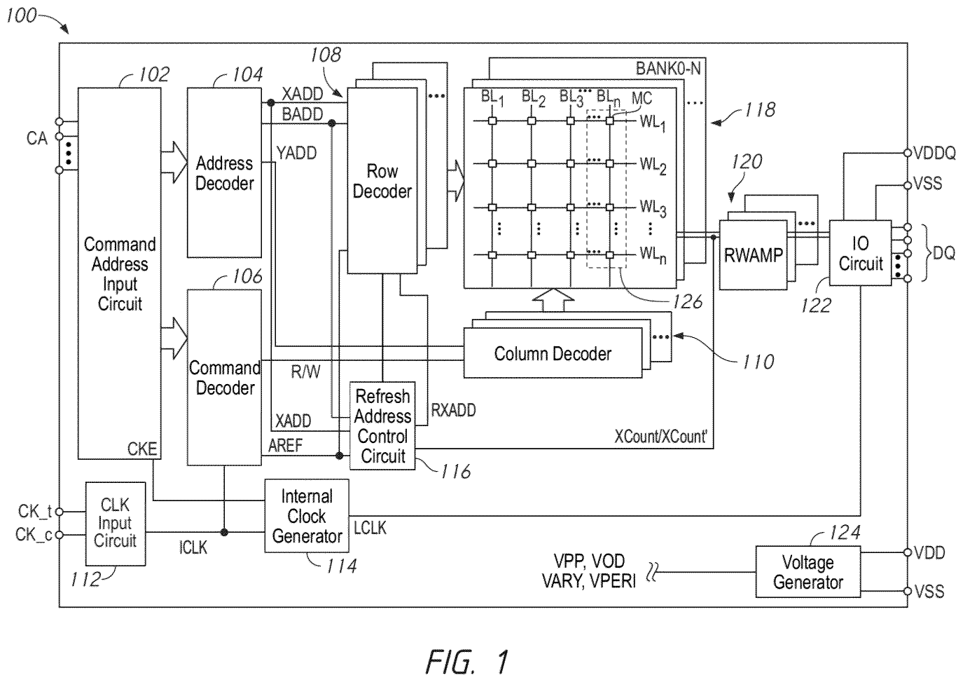

FIG. 1 is a block diagram of a semiconductor device according to at least one embodiment of the disclosure. The semiconductor device 100 may be a semiconductor memory device, such as a DRAM device integrated on a single semiconductor chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL. Some of the memory cells MC along the word lines may be counter memory cells 126. The counter memory cells 126 may be positioned at the intersection of counter bit lines and the word lines. There may be multiple counter memory cells 126 along a given word line, and collectively the values stored in the counter memory cells 126 may represent a respective access count XCount of the word line. A data bus associated with the counter memory cells 126 may be coupled to a refresh address control circuit 116. In some embodiments of the disclosure, the data bus associated with the counter memory cells 126 may be separate from the data bus which couples the other memory cells to the IO circuit 122.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL. Information may generally be read from and written to the counter memory cells 126 in an analogous fashion, except that the data in the counter memory cells 126 are read and written by the refresh address control circuit 116.

The semiconductor device 100 may employ a plurality of external terminals that include command and address (CA) terminals coupled to a command and address bus to receive commands and addresses, and a CS signal, clock terminals to receive clocks CK_t and CK_c, data terminals DQ to provide data, and power supply terminals to receive power supply potentials VDD, VSS, and VDDQ.

The clock terminals are supplied with external clocks CK_t and CK_c that are provided to an input circuit 112. The external clocks may be complementary. The input circuit 112 generates an internal clock ICLK based on the CK_t and CK_c clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a row activation command ACT. When the row activation command ACT is received, a bank address BADD and a row address XADD are timely supplied with the row activation command ACT.

The device 100 may receive an access command which is a read command. When a read command is received, a column address YADD is timely supplied with the read command, read data is read from memory cells in the memory array 118 corresponding to the row address XADD and column address YADD. The read command is received by the command decoder 106, which provides internal commands so that read data from the memory array 118 is provided to the read/write amplifiers 120. The read data is output to outside from the data terminals DQ via the input/output circuit 122. The access count XCount stored in the counter memory cells 126 of the row associated with the row address XADD are read to the refresh address control circuit 116, and an updated value of the access count XCount′ is written back to the counter memory cells 126 of the row XADD.

The device 100 may receive an access command which is a write command. When the write command is received, a column address YADD is timely supplied with the write command, write data supplied to the data terminals DQ is written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. Similar to the read operation described above, the access count XCount stored in the counter memory cells 126 of the row associated with the row address XADD are read to the refresh address control circuit 116, and an updated value of the access count XCount′ is written back to the counter memory cells 126 of the row XADD.

The device 100 may also receive commands causing it to carry out an auto-refresh operation. The refresh signal AREF may be a pulse signal which is activated when the command decoder 106 receives a signal which indicates an auto-refresh command. In some embodiments, the auto-refresh command may be externally issued to the memory device 100. In some embodiments, the auto-refresh command may be periodically generated by a component of the device. In some embodiments, when an external signal indicates a self-refresh entry command, the refresh signal AREF may also be activated. The refresh signal AREF may be activated once immediately after command input, and thereafter may be cyclically activated at desired internal timing. Thus, refresh operations may continue automatically. A self-refresh exit command may cause the automatic activation of the refresh signal AREF to stop and return to an IDLE state.

The refresh signal AREF is supplied to the refresh address control circuit 116. The refresh address control circuit 116 supplies a refresh row address RXADD to the row decoder 108, which may refresh a word line WL indicated by the refresh row address RXADD. The refresh address control circuit 116 may control a timing of the refresh operation, and may generate and provide the refresh address RXADD. The refresh address control circuit 116 may be controlled to change details of the refreshing address RXADD (e.g., how the refresh address is calculated, the timing of the refresh addresses), or may operate based on internal logic.

The refresh address control circuit 116 may selectively output a targeted refresh address (e.g., a victim address) or an automatic refresh address (auto-refresh address) as the refreshing address RXADD. The automatic refresh addresses may be a sequence of addresses which are provided based on activations of the auto-refresh signal AREF. The refresh address control circuit 116 may cycle through the sequence of auto-refresh addresses at a rate determined by AREF. In some embodiments, the sequence of auto-refresh addresses may include all the addresses in the memory bank 118. In some embodiments, the auto-refresh signal AREF may be issued with a frequency such that most or all of the addresses in the memory bank 118 are refreshed within a certain period, which may be based on an expected rate at which information in the memory cells MC decays.

The refresh address control circuit 116 may also determine targeted refresh addresses which are addresses that require refreshing (e.g., victim addresses corresponding to victim rows) based on the access pattern of nearby addresses (e.g., aggressor addresses associated with aggressor rows) in the memory array 118. The refresh address control circuit 116 may monitor accesses to the different word lines WL of the memory bank. When the row decoder 108 sends an access command to a particular row, the counter memory cells 126 along that row may have their information read to the refresh address control circuit 116 as the access count XCount. The refresh address control circuit 116 may determine an access count of the row based on the values stored in the counter memory cells 126 of the accessed row.

The refresh address control circuit 116 may determine if the accessed row is an aggressor row based on the access count from the counter memory cells 126. If the current row is not an aggressor row, the value of the access count may be changed and then the refresh address control circuit may write the new value of the access count back to the counter memory cells 126 of the accessed row. If the refresh address control circuit 116 determines that the accessed row is an aggressor, then the refresh address control circuit 116 may use the row address XADD of the accessed row to determine one or more victim row addresses and provide them as a refresh address RXADD as part of a targeted refresh operation. When the accessed row is determined to be an aggressor, the access count XCount associated with that row may be reset (e.g., to a minimum value, such as 0). In some embodiments, the refresh address control circuit 116 may queue up identified aggressor addresses (e.g., in a register) for later use in targeted refresh operations.

The refresh address RXADD may be provided with a timing based on a timing of the refresh signal AREF. The refresh address control circuit 116 may have time slots corresponding to the timing of AREF, and may provide one or more refresh addresses RXADD during each time slot. In some embodiments, the targeted refresh address may be issued in (e.g., “steal”) a time slot which would otherwise have been assigned to an auto-refresh address. In some embodiments, certain time slots may be reserved for targeted refresh addresses, and the refresh address control circuit 116 may determine whether to provide a targeted refresh address, not provide an address during that time slot, or provide an auto-refresh address instead during the time slot.

The targeted refresh address may be based on access characteristics over time of the row addresses XADD received from the address decoder 104. For example, the access characteristics may be determined based on the value of the access count XCount stored in the count memory cells 126. The refresh address control circuit 116 may use different methods to calculate a targeted refresh address based on a row address XADD identified as an aggressor address based on the access count. For example, the refresh address control circuit 116 may determine if a given row is an aggressor address, and then calculate and provide addresses corresponding to victim addresses of the aggressor address as the targeted refresh address. In some embodiments, more than one victim address may correspond to a given aggressor address. In this case the refresh address control circuit may queue up multiple targeted refresh addresses, and provide them sequentially when it determines that a targeted refresh address should be provided. The refresh address control circuit 116 may provide the targeted refresh address right away, or may queue up the targeted refresh address to be provided at a later time (e.g., in the next time slot available for a targeted refresh).

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The internal potential VPP is mainly used in the row decoder 108, the internal potentials VOD and VARY are mainly used in the sense amplifiers SAMP included in the memory array 118, and the internal potential VPERI is used in many peripheral circuit blocks.

The power supply terminals are also supplied with power supply potential VDDQ. The power supply potential VDDQ and VSS are supplied to the input/output circuit 122. The power supply potential VDDQ supplied to the power supply terminals may be the same potentials as the power supply potential VDD supplied to the power supply terminals in an embodiment of the disclosure. The power supply potential VDDQ supplied to the power supply terminals may be different potentials from the power supply potential VDD supplied to the power supply terminals in another embodiment of the disclosure. The power supply potential VDDQ supplied to the power supply terminals are used for the input/output circuit 122 so that power supply noise generated by the input/output circuit 122 does not propagate to the other circuit blocks.

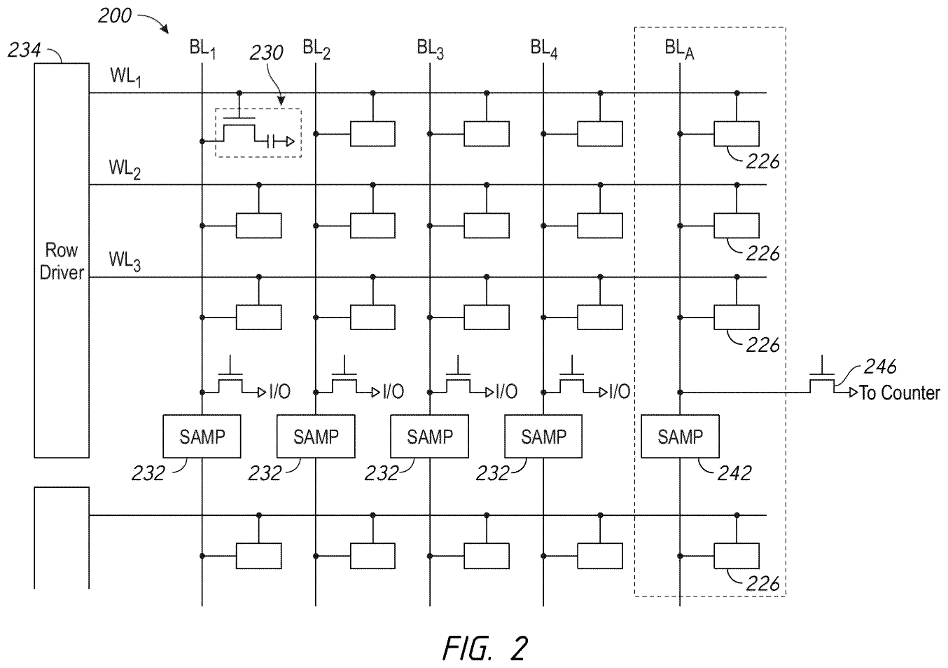

FIG. 2 is a block diagram of a memory cell array according to an embodiment of the present disclosure. The memory cell array 200 may represent an exemplary portion of a memory array, such as the memory array 118 of FIG. 1. The memory cell array 200 includes a plurality of word lines WL (rows) and bit lines BL (columns). A row driver 234 is coupled to the rows. A plurality of memory cells MC, such as example memory cell 230, are located at the intersection of the rows and columns. Memory cells along each of the word lines WL may be counter memory cells 226. Each of the bit lines BL may be coupled to a respective sense amplifier 232.

Each of the memory cells MC may store information. In some embodiments, the information may be stored as a binary code, and each memory cell MC may store a bit, which may be either at a logical high or a logical low level. Example memory cell 230 shows a particular implementation which may be used to store a bit of information in some embodiments. Other types of memory cells may be used in other examples. In the example memory cell 230, a capacitive element stores the bit of information as a charge. A first charge level may represent a logical high level, while a second charge level may represent a logical low level. One node of the capacitive element is coupled to a reference voltage (e.g., VSS). The other node of the capacitive element is coupled to a switch. In the example memory cell 230, the switch is implemented using a transistor. An activation node of the switch (e.g., the gate of the transistor) is coupled to the word line. The word line WL may be accessed by the row driver 234 setting a voltage along the word line such that the switches in the memory cells MC are activated to provide the charge level of the capacitive elements (or other bit storage element) to the associated bit lines BL.

The sense amplifiers 232 may read or write a value of a bit of information along the bit line BL to memory cell MC at the accessed word line WL. The sense amplifiers may convert a signal along the bit line to a signal which is ‘readable’ by other elements of the memory device (e.g., by amplifying a voltage). The signal on the bit lines may be provided to an input/output circuit (e.g., input/output circuit 122 of FIG. 1) via a respective column select switch, which may be a column select transistor.

In an example read operation, when a word line WL is accessed, the memory cells MC may provide their charge onto the coupled bit lines BL which may cause a change in a voltage and/or current along the bit line BL. The respective sense amplifier 232 may determine a logical level of the accessed memory cell MC based on the resulting voltage and/or current along the bit line BL, and may provide a signal corresponding to the logical level through the column select transistor to the input/output circuit.

In an example write operation, the sense amplifiers 232 may receive a signal indicating a logical level to be written to the accessed memory cells from the input/output circuit. The sense amplifier 232 may provide a voltage and/or current along the coupled bit line BL (e.g., along the bit lines with active column select transistors) at a level corresponding to the logical level to be written. The voltage and/or current along the bit line BL may charge the capacitive element at the intersection of the bit line with an accessed word line to a charge level associated with the written logical level. In this manner, by specifying the row which is accessed, and which bit lines to record data from (and/or write data to), specific memory cells MC may be accessed during one or more operations of the memory device.

During an example refresh operation (either targeted or auto-refresh), the word line WL to be refreshed may be read, and then logical value read from each of the memory cells along that row may be written back to the same memory cells. In this manner the level of charge in the refreshed memory cells MC may be restored to the full value associated with the logical level stored in that memory cell.

Certain memory cells along each of the word lines may be counter memory cells 226. The counter memory cells 226 may generally be similar to the other memory cells of the memory array 200. In some embodiments, the counter memory cells 226 may be physically the same as the other memory cells MC. However, rather than being coupled to the input/output circuit of the memory, the counter memory cells 226 may be coupled to the refresh address control circuit (e.g., refresh address control circuit 116 of FIG. 1). The refresh address control circuit may read and/or write a value of an access count, which may be stored as a binary number in the counter memory cells 226 of a given word line. In some embodiments, the refresh address control circuit may be in an area local to the counter memory cell 226, and so the communication of the refresh address control circuit and the counter memory cells 226 may be very rapid.

In some embodiments, the counter memory cells 226 may be organized along particular bit lines of the memory array 200. Thus, there may be counter bit lines (and associated counter sense amplifiers 242) which are coupled to the counter memory cells 226. The counter memory cells 226 may be arranged at the intersection of the counter bit lines and the word lines. The counter bit lines may include counter select transistors 246 (similar to the column select transistors), which selectively allow data from the counter bit lines to be read to the counter of the refresh address control circuit. The counter bit lines and counter sense amplifiers 242 may be coupled through a data bus to a counter of a refresh address control circuit. In some embodiments, the counter memory cells 226 may be positioned along an end of the memory array 200. This may decrease a length of the counter data bus. For example, if there are some number n of counter memory cells 226 along each word line, the counter memory cells 226 may be the first n memory cells of the word line, or the last n memory cells of the word line. SAMPs 232 and 242 may have complementary bit lines and memory cells on opposite sides of the SAMPs 232 and 242, as illustrated.

For clarity of illustration, only a few word lines WL and bit lines BL (and their corresponding memory cells MC) are shown in FIG. 2. More word lines WL and bit lines BL may be provided in a memory array of the present disclosure. Similarly, FIG. 2 only shows a single counter bit line of counter memory cells 226. However, each word line WL may have a number of counter memory cells 226 based on an expected maximum value of access count that may need to be stored in the counter memory cells 226. In some embodiments, there may be between 8 and 16 counter memory cells 226 along each word line. More or fewer counter memory cells 226 may be used in other examples.

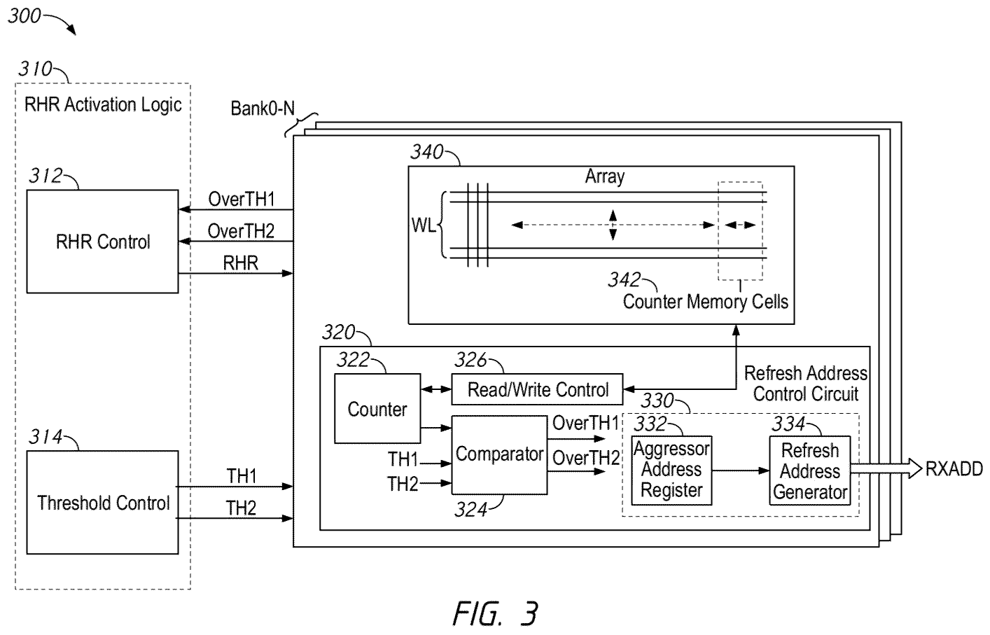

FIG. 3 is a block diagram of a RHR control logic 300 according to an embodiment of the present disclosure. The RHR control logic includes RHR activation logic 310, and further includes refresh address control circuit 320 associated with each memory bank. In some embodiments, portions or all of the RHR control logic 300 may be included in the refresh address control circuit 116 and/or associated with respective memory banks of the memory array 118 of FIG. 1. The refresh address control circuit 320 is shown to represent that in certain embodiments, that these components may be repeated for each of the banks of memory. For the sake of brevity, components for only a single bank will be described.

The RHR activation logic 310 includes RHR control 312 and threshold control 314. RHR control 312 provides an active RHR activation signal RHR when one or more of threshold signals over TH1 and over TH2 are active. An active over TH1 signal indicates that an access count for a row exceeds a threshold TH1 and an active over TH2 signal indicates that the access count for a row exceeds a threshold TH2. Exceeding one or more of the thresholds TH1 and/or TH2 may suggest a row is considered an aggressor row. The active RHR signal causes a targeted refresh operation to rows of memory of the memory bank, for example, victim rows of memory that are physically neighboring the aggressor row. The RHR activation logic 310 further includes threshold control 314 that provides threshold values to the refresh address control circuit 320 of each of the memory banks. Two threshold values may be used in some embodiments of the disclosure. One of the threshold values may be used to trigger targeted refresh for a first set of neighboring victim rows, and the other threshold value may be used to trigger targeted refresh for a second set of neighboring victim rows. In some embodiments of the disclosure, the first set of neighboring victim rows may be physically next to the aggressor row (e.g., +/−1) and the second set of neighboring victim rows may be two physical rows from the aggressor row (e.g., +/−2).

Each memory bank may be associated with a respective refresh address control circuit 320. The refresh address control circuit 320 includes a counter 322, a comparator 324, read/write control 326, and address logic 330. When a row of the memory array 340 is accessed, the values of the counter memory cells 342 along that row are read to the counter 322 as controlled by read/write control 326. The counter 322 may determine a value of the access count for that row based on the values read from the counter memory cells 340. The counter 322 may be a count control circuit, which may manage a value of the count stored in the counter memory cells 342 (e.g., by reading the raw data in the counter memory cells 342 as a numerical value, writing new numerical values to the counter memory cells 342 etc.). The counter 322 may provide the count value to a threshold comparator 324, which may determine if the value of the count exceeds one or more of thresholds TH1 and TH2 (e.g., if the value is greater than the threshold). The thresholds TH1 and TH2 are provided by the threshold control 314 of the RHR activation logic 310. If the value does not exceed the threshold (e.g., if the value is less than or equal to the threshold), then the counter 322 may increment a value of the count and write the incremented count back to the counter memory cells 342 as controlled by the read/write control 326. If the value does exceed one or more of the thresholds TH1 and TH2, then the current address XADD of the accessed row may be determined to be an aggressor address. When the value of the count exceeds the threshold TH1 the comparator 324 provides an active threshold signal over TH1, and when the value of the count exceeds the threshold TH2 the comparator 324 provides an active threshold signal over TH2. The active threshold signal over TH1 or over TH2 causes the RHR control 312 to provide an active RHR activation signal RHR. The active RHR activation signal RHR causes the address logic 330 of the refresh address control circuit 320 to provide row addresses for targeted refreshes. A current address for a row that has been identified as an aggressor row is stored in aggressor address register 332 of the address logic 330, and the address for the aggressor row is used by refresh address generator 334 to provide addresses RXADD for targeted refresh. In some embodiments of the disclosure, the address logic 330 provides addresses RXADD for targeted refresh of a first set of neighboring victim rows when the RHR activation signal RHR is active for exceeding the threshold TH1, and the address logic 330 provides addresses RXADD for targeted refresh of a second set of neighboring victim rows when the RHR activation signal RHR is active for exceeding the threshold TH2.

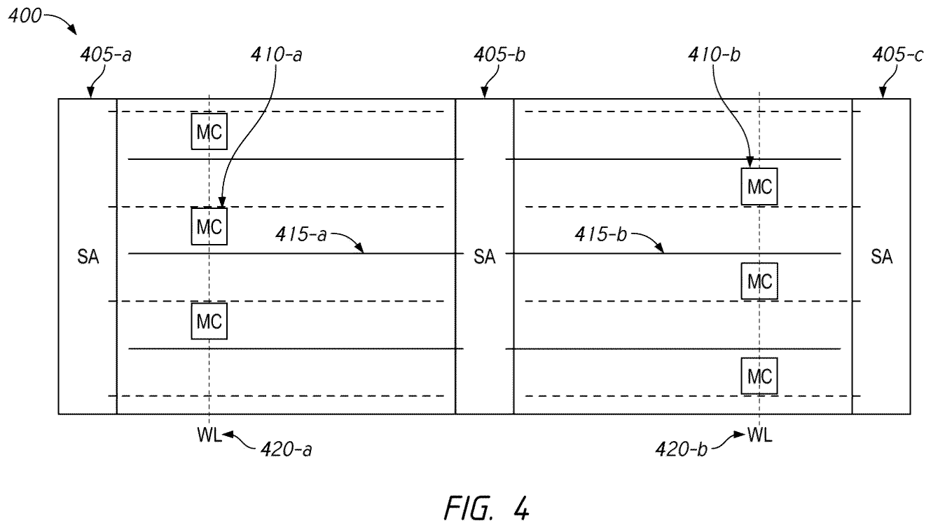

FIG. 4 is a schematic diagram of a memory system 400 according to an embodiment of the disclosure. In some examples, sense amplifier region 405-a may, in some embodiments, include SAMPs 232, 242, or a combination thereof.

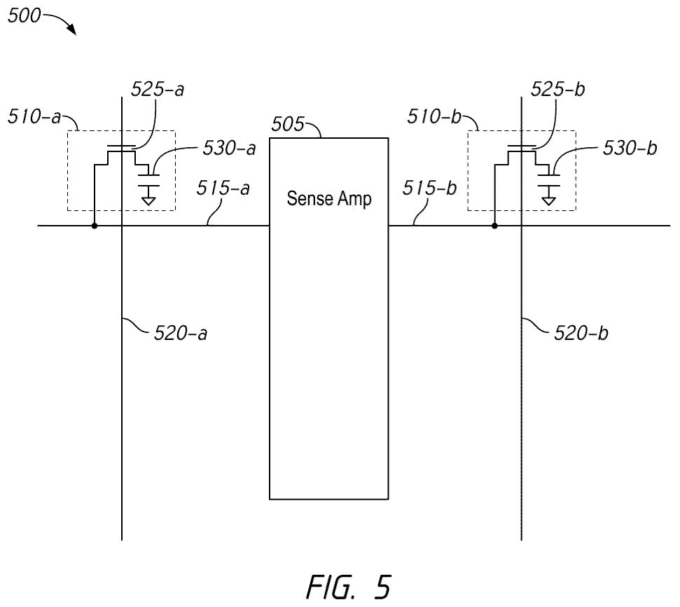

Memory system 400 may include sense amplifier region 405-a, 405-b, 405-c, memory cell 410-a, memory cell 410-b, digit line 415-a, digit line 415-b, word line 420-a, and word line 420-b. The term “digit line” may be used interchangeably with the term “bit line.” In some cases, digit line 415-a may be a target digit line, and digit line 415-b may be a reference digit line. Memory cell 410-a, 410-b, or both, may be counter memory cells that, when taken together or when taking together with additional memory cells, may represent an access count for a given row. Sense amplifier regions 405-a, 405-b, 405-c may each include one or more sense amplifiers. For example, one sense amplifier may correspond to one memory cell on one side of the sense amplifier, and another memory cell on the other side of the sense amplifier (see FIG. 5).

Sense amplifier regions 405 may include additional sense amplifiers, each sense amplifier coupled to other memory cells 410. In some cases, word lines 420 may activate multiple memory cells 410 to which they are connected. For example, word line 420-a may activate memory cell 410-a, and word line 420-b may activate memory cell 410-b.

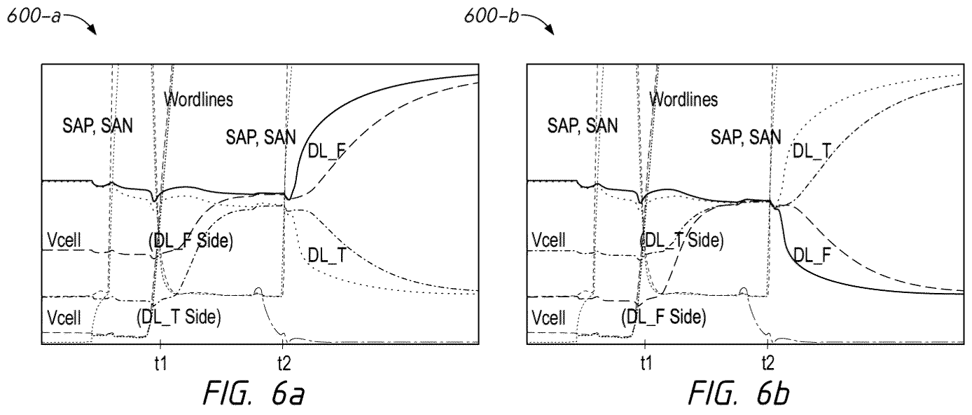

On start-up, there may be residual charge that is stored in memory cells 410-a and 410-b, no charge, or some combination thereof. Different scenarios for memory cells with different charges are further explained in FIG. 6. Word lines 420-a and 420-b may be activated. A sense amplifier in sense amplifier region 405-b may sense these voltages, determine which digit line has a greater voltage, and drive the digit line with the greater voltage to a high logic level voltage (e.g., to a supply voltage (e.g., Vdd)) and drive the digit line with the lesser voltage to a low logic level voltage (e.g., to ground). Since the word lines 420-a and 420-b are still activated, the memory cells 410-a and 410-b coupled to the respective digit lines 415-a and 415-b are charged to Vdd or ground. The word lines 420-a and 420-b are deactivated, and thus the corresponding charges are stored to each memory cell. Memory cells 410-a and 410-b now store complementary logic values (e.g., 1 and 0), depending on which digit line was driven high or low.

In this way, the initialized values of memory cells 410-a and 410-b (e.g., counter memory cells that count refreshes) are based on any residual charges that remain on the memory cells (e.g., prior to start-up). As a result, the initialized values of the memory cells are random, pseudo-random, essentially random, or arbitrary. Such techniques for initialization of the counter memory cells may make it more difficult for a malicious user to determine the counter value of the counter memory cells for use in row hammer attacks or to cause some other performance drop in the system (e.g., a waterfall or cascade attack). Further explanation may be found at least in FIG. 5.

FIG. 5 is a schematic diagram of a memory system 500 according to an embodiment of the disclosure. In some examples, sense amplifier 505 may, in some embodiments, be included in SAMPs 232, 242, sense amplifier regions 405, or a combination thereof.

Memory system 500 may include sense amplifier 505, memory cell 510-a, memory cell 510-b, target digit line 515-a (true), reference digit line 515-b (complementary), word line 520-a, and word line 520-b. Memory cell 510-a may include transistor 525-a and capacitor 530-a, and memory cell 510-b may include transistor 525-b and capacitor 530-b. Memory cell 510-a, 510-b, or both, may be counter memory cells that, when taken together or when taking together with additional memory cells, may represent an access count for a given row.

On start-up, there may be residual charge that is stored in memory cells 510-a and 510-b, no charge, or some combination thereof. Different scenarios for memory cells with different charges is further explained in FIG. 6. Word lines 520-a and 520-b may be activated, and the voltages of the respective capacitors 530-a and 530-b may be provided to the digit lines 515-a and 515-b. The sense amplifier 505 may sense these voltages, determine which digit line has a greater voltage, and drive the digit line with the greater voltage to a high logic level voltage (e.g., to a supply voltage (e.g., Vdd)) and drive the digit line with the lesser voltage to a low logic level voltage (e.g., to ground). Since the word lines 520-a and 520-b are still activated, the respective capacitors 530-a and 530-b coupled to the respective digit lines 515-a and 515-b are charged to Vdd or ground. The word lines 520-a and 520-b are deactivated, and thus the corresponding charges are stored to each capacitor. Memory cells 510-a and 510-b now store complementary logic values (e.g., 1 and 0), depending on which digit line was driven high or low.

For example, on start-up or just before start-up, or during some other time, memory cell 510-a (e.g., capacitor 530-a) may store a residual charge, and memory cell 510-b (e.g., capacitor 530-b) may store a lesser residual charge. Such residual charges may be front previous operation of the memory system 500, or from any other operation, including start-up and/or initialization. Word line 520-a may be activated, which may activate transistor 525-a. The residual voltage from capacitor 530-a may be provided to digit line 515-a. Sense amplifier 505 may sense the voltage from digit line 515-a. Word line 520-b may be activated, which may activate transistor 525-b. The lesser residual voltage from capacitor 530-b may be provided to digit line 515-b. Sense amplifier 505 may sense the voltage from digit line 515-b.

Sense amplifier 505 may amplify the differential voltage between the digit lines based on which digit line has a higher voltage value. In the present example, digit line 515-a has a higher voltage than digit line 515-b, sense amplifier 505 may amplify digit line 515-a higher (e.g., Vdd), and may drive digit line 515-b lower (e.g., to ground).

Since word line 520-a is still activated, the amplified voltage on digit line 515-a is provided to capacitor 530-a. Since word line 520-b is still activated, the lower voltage on digit line 515-b is provided to capacitor 530-b. Word lines 520-a and 520-b are deactivated, and the respective charged voltages on the capacitors are stored. Memory cell 510-a stores a logical “1” and memory cell 510-b stores a logical “0”.

In this way, the initialized values of memory cells 510-a and 510-b (e.g., counter memory cells that count refreshes) are based on any residual charges that remain on the memory cells (e.g., prior to start-up). In this way, the initialized values of the memory cells are random, pseudo-random, essentially random, or arbitrary. Such techniques for initialization of the counter memory cells may make it more difficult for a malicious user to determine the counter value of the counter memory cells for use in row hammer attacks or to cause some other performance drop in the system (e.g., a waterfall or cascade attack).

FIGS. 6a and 6b are timing diagrams 600-a and 600-b according to embodiments of the disclosure. Timing diagrams 600 and 600b may represent timings in accordance with various processes of FIG. 4, 5, or both. Timing diagram 600-a may represent a scenario where the true memory cell has an initial charge that is less than an initial charge of the complementary memory cell (or in other words, the initial charge of the complementary memory cell is greater than the initial charge of the true memory cell). Timing diagram 600-b may represent a scenario where the true memory cell has an initial charge that is greater than an initial charge of the complementary memory cell (or in other words, the initial charge of the true memory cell is greater than the initial charge of the complementary memory cell). Additional potential combinations may be described in FIG. 6, such as when both memory cells have a same or similar initial charge, or when both memory cells have no charge or essentially no charge.

On start-up, there may be residual charge that is stored in memory cells 510-a and 510-b, no charge, or some combination thereof. For example, in FIG. 6a, the residual charge for the true memory cell (e.g., memory cell 510-a) may be less than the residual charge for the complementary memory cell (e.g., memory cell 510-b). In FIG. 6b, the residual charge for the true memory cell (e.g., memory cell 510-a) may be greater than the residual charge for the complementary memory cell (e.g., memory cell 510-b).

The timing diagram for FIG. 6a will be explained with reference to the circuit elements of FIG. 5.

Prior to activation of word lines 520-a and 520-b at time t1, digit lines 515-a and 515-b may be precharged (in the present example, digit line 515-a corresponds to DL_T and digit line 515-b corresponds to DL_F). The voltage in the two memory cells 510-a and 510-b may be their respective charges (e.g., 0 mV and 200 mV, respectively, as shown in FIG. 6a). After word lines 520-a and 520-b are activated, the voltages of the respective capacitors 530-a and 530-b may be provided to the digit lines 515-a and 515-b. As shown between t1 and 12, the voltages of the true digit line 515-a DL_T is driven lower than the voltage of the complementary digit line 515-b DL_F from charge sharing. The voltages of memory cell 510-a and digit line 515-a eventually match in voltage, and 510-b and 515-b eventually match in voltage. At t2, the sense amplifier 505 is activated via activation signals (e.g., SAP, SAN), and the sense amplifier 505 amplifies the digit line voltages based on the sensed difference in the digit lines due to the difference in the voltages initially stored in the memory cells. The sense amplifier 505 may sense these voltages, determine which digit line has a greater voltage (e.g., relative to their initial voltage difference before charge sharing, or a greater change in voltage downward indicating a lower charged memory cell), and drive the digit line with the greater voltage (or lesser-changed voltage) up as seen after t2, and drive the digit line with the lesser voltage (or greater-changed voltage) down as seen after t2. For example, at t2, the sense amplifier determines that the true digit line DL_T has a lower voltage than the complementary digit line DL_F, and thus amplifies this difference after t2.

The timing diagram for FIG. 6b will be explained with reference to the circuit elements of FIG. 5.

Prior to activation of word lines 520-a and 520-b at time t1, digit lines 515-a and 515-b may be precharged. The voltage in the two memory cells 510-a and 510-b may be their respective charges (e.g., 200 mV and 0 mV, respectively, as shown in FIG. 6b). After word lines 520-a and 520-b are activated, the voltages of the respective capacitors 530-a and 530-b may be provided to the digit lines 515-a and 515-b. As shown between t1 and t2, the voltage of the true digit line DL_T is driven low, but the voltage of the complementary digit line DL_F is driven even lower (due to charge sharing) because the complementary digit line has 0 mV while the true digit line has 200 mV. Since the complementary digit line was higher to begin with before t1, the voltages of the true and complementary lines are similar at t2, indicating that the true memory cell had a higher voltage than that of the complementary memory cell. The voltages of memory cell 510-a and digit line 515-a eventually match in voltage, and 510-b and 515-b eventually match in voltage. At t2, the sense amplifier 505 is activated via activation signals (e.g., SAP, SAN), and the sense amplifier 505 amplifies the digit line voltages based on the sensed difference in the digit lines due to the difference in the voltages initially stored in the memory cells. The sense amplifier 505 may sense these voltages, determine which digit line has a greater voltage (e.g., relative to their initial voltage difference before charge sharing, or a greater change in voltage downward indicating a lower charged memory cell), and drive the digit line with the greater relative voltage (or lesser-changed voltage) up as seen after t2, and drive the digit line with the lesser voltage (or greater-changed voltage) down as seen after t2. For example, at t2, the sense amplifier determines that the true digit line DL_T has a lesser relative voltage change than the complementary digit line DL_F, and thus drives DL_T up.

In some other examples, both true and complementary memory cells may have the same or a similar residual charge or no residual charge. In such examples, the sense amplifier may simply determine which digit line has a greater voltage after charge sharing, and amplify that one, and drive the other digit line down. This is because the true and complementary digit lines have some voltage difference even before charge sharing, and this difference does not change upon charge sharing since the charge in both the true and complementary memory cells is the same or similar, or both zero. In this case, the digit line that had the greater voltage to begin with (e.g., just before t1 in FIG. 6a or 6b) will be amplified merely due to the pre-existing voltage difference). In some cases, the true digit line may be the digit line that is initially driven higher rather than the complementary digit line which is shown in FIGS. 6a and 6b.

The initialized values of memory cells 510-a and 510-b (e.g., counter memory cells that count refreshes) are based on any residual charges that remain on the memory cells (e.g., prior to start-up). In this way, the initialized values of the memory cells are random, pseudo-random, essentially random, or arbitrary. The residual charges on the memory cells inform the operation of the sense amplifier, namely through identification of which memory cell holds the greater charge. Then, the sense amplifier writes back a “1” to the memory cell with the higher residual charge, and a “0” to the memory cell that has a lower residual charge. Such techniques for initialization of the counter memory cells may make it more difficult for a malicious user to determine the counter value of the counter memory cells for use in row hammer attacks or to cause some other performance drop in the system (e.g., a waterfall or cascade attack).

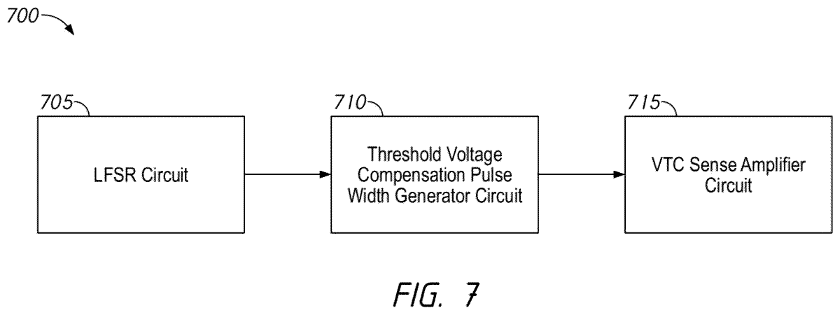

FIG. 7 is a block diagram of a sense amplifier threshold voltage compensation pulse width system 700 according to an embodiment of the disclosure. The sense amplifier threshold voltage compensation pulse width system 700 may include a linear feedback shift register (LFSR) 705, a threshold voltage compensation (VtC) pulse width generator circuit 710, and VtC sense amplifier circuit 715.

The LFSR 705 may generate a multi-bit (e.g., four bits) pseudo-random number or series of values (e.g., in binary). For example, LFSR 705 may generate 0001, 0011, 0010, 1010, etc. LFSR 705 may provide the number to the VtC pulse width generator circuit 710. The VtC pulse width generator circuit 710 may provide a VtC pulse having a pulse width based on the number provided. In some embodiments of the disclosure, some values from the LFSR 705 may map to particular VtC pulse width settings. For example, a value of 1000 may correspond to a first VtC pulse width and a value of 0001 may correspond to a second VtC pulse width, with the first VtC pulse width wider than the second VtC pulse width. Other mapping schemes may also be used. The VtC pulse width generator circuit 710 provides an indication of a VtC pulse width to VtC sense amplifier 715, such as sense amplifier 505.

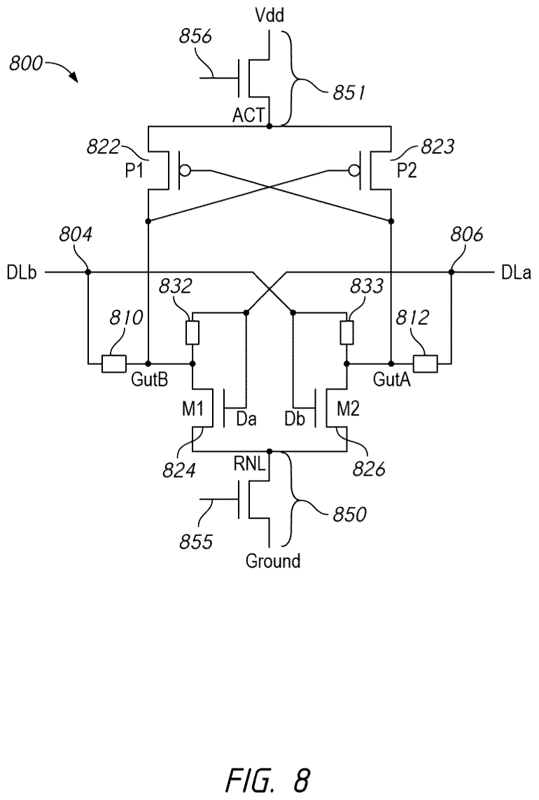

FIG. 8 is a schematic diagram of a sense amplifier 800 according to an embodiment of the disclosure. Sense amplifier 800 may include a threshold voltage compensation sense amplifier. In some embodiments of the disclosure, the sense amplifier 800 may be included in the VtC sense amplifier circuit 715 of FIG. 7.

The sense amplifier 800 selectively amplifies a signal on the digit lines DLb and DLa. The sense amplifier 800 includes a pair of ISO switches 810 and 812 (e.g., NMOS switches or isolation transistors). These ISO switches 810 and 812 may be coupled to isolation control signal ISO (not pictured) respectively. The sense amplifier 800 includes p-type transistors P1 822 and P2 823 and n-type transistors M1 824 and M2 826. The transistor P1 822 has a node that is coupled with node ACT, a node coupled to a node GutB, and a gate coupled to a node GutA. The node GutB may be coupled through a transistor 832 to the bit line DLa, and the node GutA may be coupled through a transistor 833 to the bit line DLb. The transistors 832 and 833 are provided a control signal BLCP (not shown in FIG. 8). The transistors 832 and 833 are activated by an active BLCP control signal (e.g., active high logic level BLCP control signal). The transistor P2 823 has a node that is coupled with the node ACT, a node coupled to node GutA, and a gate coupled to node GutB. The transistor M1 has a node coupled to the node GutB, a node that is coupled with node RNL, and a gate coupled to the bit line DLa. The transistor M2 has a node coupled to the node GutA, a node that is coupled to node RNL, and a gate coupled to the bit line DLb. During access operations, a supply voltage (e.g., Vdd) is provided to the ACT node and ground is provided to the RNL node to activate the sense amplifier 800.

The first ISO switch 810 is coupled between the bit line DLb and the node GutB. The first ISO switch 810 may act as a switch and may couple the bit line DLb to the node GutB when activated. The first ISO switch 810 may be an n-type transistor. The second ISO switch 812 is coupled between the bit line DLa and the node GutA. When activated, the second ISO switch 812 couples the bit line DLa 806 to the gut node GutA. Gates of the first ISO switch 810 and the second ISO switch 812 are provided an ISO signal, which when active (e.g., active logical high) activates the first ISO switch 810 and the second ISO switch 812.

In operation, a charge state of an activated memory cell is provided to the sense amplifier 800, and when the sense amplifier 800 is activated by providing a supply voltage (e.g., Vdd) to the ACT node and ground is provided to the RNL node, the charge state is amplified, resulting in one of the digit lines DLb or DLa being driven to the supply voltage and the other digit line being driven to ground.

A drive transistor 850 is coupled to the RNL node and a drive transistor 851 is coupled to the ACT node. When the drive transistor 850 is activated, ground is provided to the RNL node, and when the drive transistor 851 is activated, a supply voltage (e.g., Vdd) is provided to the ACT node. The drive transistors 850 and 851 are activated to activate the sense amplifier during one or more phases of sense amplification (e.g., threshold voltage compensation phase, sense amplifier activation phase). The drive transistor 850 is activated by a control signal 855 and the drive transistor 851 is activated by a control signal 856. The duration of a voltage of a control signal 855 and/or control signal 856 applied to the gate of the drive transistor 850 and/or drive transistor 851 may indicate or include the duration of the corresponding phase (e.g., threshold voltage compensation phase, sense amplifier amplification phase). As such, the phase width is increased or decreased accordingly. In some embodiments of the disclosure, an output from a VtC pulse width generator (e.g., VtC pulse width generator circuit 710 of FIG. 7) may extend or reduce the duration the voltage is applied to the gate of the transistor to activate the drive transistor 850 and/or drive transistor 851, by widening or shortening the VtC pulse width.

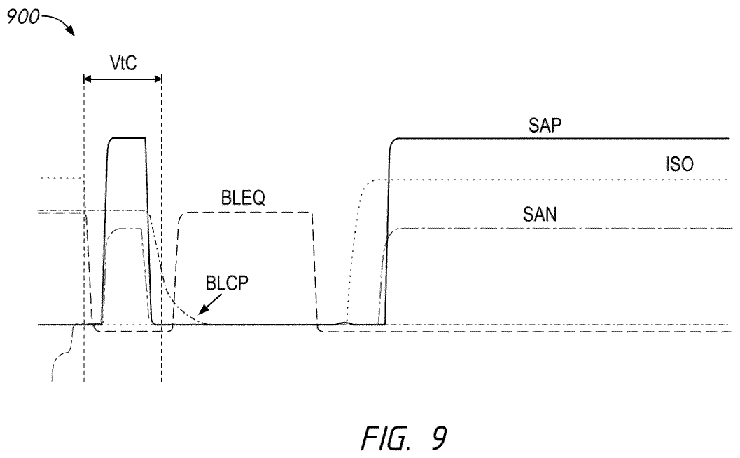

FIG. 9 illustrates a timing diagram according to an embodiment of the present invention. The timing diagram illustrates a sequence of control signals associated with the operation of the voltage-threshold compensation (VtC) sense amplifier 800 of FIG. 8.

In the initial phase, a control signal BLCP (e.g., coupled to the gate of transistors 832 and 833 in FIG. 8) is at a high logic level, thereby activating the transistors 832 and 833 and preparing the sense amplifier 800 for operation. The isolation (ISO) control signal is also at a high logic level to activate ISO switches 810 and 812 to provide a current path between bit line DLb and node GutB and provide a current path between bit line DLa and node GutA. Concurrently, the bit line equalization (BLEQ) control signal (not shown in FIG. 8) is high, facilitating the equalization of the voltages on the bit lines DLb and DLa. The sense amplifier enable signals, namely sense amplifier positive (SAP) and sense amplifier negative (SAN), are at a low and negative logic level respectively, indicating the sense amplifier is in a deactivated state.

During the threshold voltage compensation (VtC) phase, the SAP and SAN control signals transition to a high logic level, activating the sense amplifier. The BLCP control signal remains at a high logic level, ensuring the gate and drain of transistors M1 824 and M2 826 are coupled (e.g., diode connected). The BLEQ control signal transitions to a low logic level, ceasing the voltage equalization on the bit lines. The ISO control signal is at a low logic level during this phase, meaning the bit line DLb is isolated from the node GutB and the bit line DLa is isolated from the node GutA. The VtC phase width (e.g., via the duration of SAN) may be controlled by a VtC pulse width generator (e.g., VtC pulse width generator circuit 710 of FIG. 7), for example, by an activation width of the control signal 855 and/or control signal 856 to the drive transistor 850 and/or drive transistor 851 controlling the phase width. As a result of the VtC phase, a compensation voltage may be developed at one or both of the nodes DLb and/or DLa.

Following the post-VtC phase, the BLCP, SAP, ISO, and SAN control signals transition to a low logic level, deactivating the bit line precharge and sense amplifier functions. The BLEQ control signal transitions to a high logic level, facilitating a re-equalization of the voltages on the bit lines in preparation for the subsequent operational cycle while the nodes GutB and GutA retain their voltage (e.g., compensation voltage).

In the final phase, the SAP, ISO, and SAN control signals transition back to a high logic level, activating the sense amplifier to amplify a voltage difference on the bit lines DLb and DLa. The BLCP and BLEQ control signals remain at a low logic level, indicating that the bit lines are neither being precharged nor equalized.

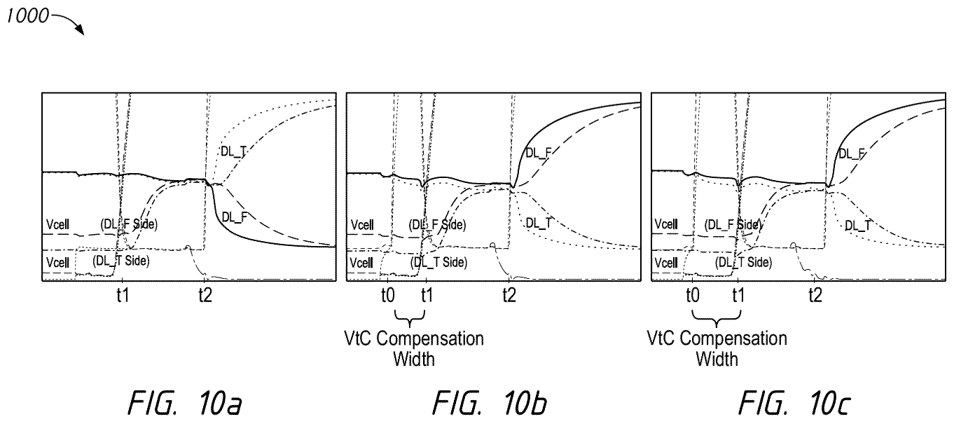

FIGS. 10a, 10b, and 10c illustrate timing diagrams according to embodiments of the disclosure. Timing diagrams 1000-a, 1000-b, and 1000-e may represent timings in accordance with various processes related to VtC compensation of a VtC sense amplifier (e.g., VtC sense amplifier 800 of FIG. 8), where the sense amplifier may be coupled to two complementary memory cells at digit line a and digit line b. Timing diagram of FIGS. 10a, 10b, and 10c may represent a scenario where the true memory cell and complementary memory cell have similar residual charge. In FIGS. 10a, 10b, and 10c and associated disclosure, the enhanced random or pseudo-random aspects of the embodiment may be attributable at least in part to the random VtC pulse width settings, for example, as provided by a VtC pulse width generator, such as VtC pulse width generator circuit 710 of FIG. 7. Though, since the residual charge is essentially random already, an additional layer of randomness may be introduced through the present techniques.

FIG. 10a illustrates a scenario where VtC is under-compensated (e.g., width is less than 3 nanoseconds). That is, the VtC pulse width is shorter compared to the VtC pulse width of FIG. 10b. If the VtC pulse width is too short, the sense amplifier may not have sufficient time to fully compensate for the threshold voltage mismatch. As a result, the sense amplifier might not correctly sense and amplify the small voltage difference between the bit lines. This may lead to incorrect data being read from the memory cells, resulting in read errors. However, in the present invention, different values being written back to memory cells is desirable to increase the randomness in the initialization of the counter memory cells.

During the precharge phase before t1, both bit lines are brought to an equal potential by the bit line precharge circuit (BLCP high). This sets up the bit lines for sensing the small voltage difference caused by the memory cell.

Activation of the word line at t1 connects a specific memory cell to the bit lines. The stored charge in the memory cell (representing a binary “0” or “1”) causes a small voltage difference between the bit lines.

As an example of under-compensated VtC, FIG. 10a does not include a VtC phase. Generally, if the VtC pulse width is under-compensated (i.e., too short), the sense amplifier may not have enough time to properly compensate for the threshold voltage mismatch between the transistors of the sense amplifier. In the case of FIG. 10a, the width of the VtC pulse is zero.

At t2, the sense amplifier senses the small voltage difference between the bit lines. Because of the under-compensation, the sense amplifier might not accurately amplify this small voltage difference, that is, a degree of randomness may be introduced in the sensing of the memory cells. The bit line that was slightly more positive may be driven to a high voltage, and the bit line that was slightly more negative (or just less positive) may be driven to a low voltage. In the case of FIG. 10a, the true digit line DL_T is higher, so the sense amplifier drives it higher. The complementary digit line DL_C is lower, so the sense amplifier drives it lower.

FIG. 10b illustrates a scenario where VtC is compensated more than the example of FIG. 10a (e.g., compensated at trip point). For example, the VtC pulse width may be a default width. If the VtC pulse width is the default, the sense amplifier may have sufficient time to compensate for the threshold voltage mismatch. As a result, the sense amplifier may correctly sense and amplify the small voltage difference between the bit lines. In the present invention, correct values being written back to memory cells is desirable to increase the randomness in the initialization of the counter memory cells, since proper compensation is an alternative to under-compensation. As previously discussed, the VtC pulse width may be randomized, for example, randomly selected by the LESR 705 and VtC pulse width generator circuit 710 in FIG. 7.

During the precharge phase before to, both bit lines are brought to an equal potential by the bit line precharge circuit (BLCP high). This sets up the bit lines for sensing the small voltage difference caused by the memory cell.

The sense amplifier enable signals, SAP and SAN, activate the sense amplifier at the beginning of the VtC compensation phase at t0. The VtC phase begins and the VtC pulse width dictates the duration of this phase (from t0 to t1). This is contrasted with the noticeable lack of a VtC phase in the example of FIG. 10a.

Generally, if the VtC pulse width is compensated, the sense amplifier may have enough time to compensate for the threshold voltage mismatch between the transistors of the sense amplifier.

Activation of the word line at t1 connects a specific memory cell to the bit lines. The stored charge in the memory cell (representing a binary “0” or “1”) causes a small voltage difference between the bit lines. The VtC phase also stops at t1.

At t2, the sense amplifier senses the small voltage difference between the bit lines. The bit line that was slightly more positive may be driven to a high voltage, and the bit line that was slightly more negative (or just less positive) may be driven to a low voltage. In the case of FIG. 10b, the complementary digit line DL_F is higher, so the sense amplifier drives it higher. The true digit line DL_T is lower, so the sense amplifier drives it lower.

FIG. 10c illustrates a scenario where VtC is over-compensated (e.g., pulse width is greater than a default VtC pulse width of FIG. 10b). That is, the VtC pulse width is relatively long. If the VtC pulse width is too long, the sense amplifier may overcompensate for the threshold voltage mismatch. This may distort the voltage difference between the bit lines, potentially leading to incorrect data being read from the memory cells. However, in the present invention, different values being written back to memory cells is desirable to increase the randomness in the initialization of the counter memory cells.

During the precharge phase before to, both bit lines are brought to an equal potential by the bit line precharge circuit (BLCP high). This sets up the bit lines for sensing the small voltage difference caused by the memory cell.

The sense amplifier enable signals, SAP and SAN, activate the sense amplifier at the beginning of the VtC phase. The VtC phase begins and the VtC pulse width dictates the duration of this phase (from t0 to t1).

Generally, if the VtC pulse width results in over-compensated VtC (i.e., too long), the sense amplifier may over-compensate for the threshold voltage mismatch between the transistors of the sense amplifier.

Activation of the word line at t1 connects a specific memory cell to the bit lines. The stored charge in the memory cell (representing a binary “0” or “1”) causes a small voltage difference between the bit lines. The VtC phase also stops at t1.

At t2, the sense amplifier senses the small voltage difference between the bit lines. Because of the over-compensation, the sense amplifier might not accurately amplify this small voltage difference, that is, a degree of randomness may be introduced in the sensing of the memory cells. The bit line that was slightly more positive may be driven to a high voltage, and the bit line that was slightly more negative (or just less positive) may be driven to a low voltage. In the case of FIG. 10c, the complementary digit line DL_F is higher, so the sense amplifier drives it higher. The true digit line DL_T is lower, so the sense amplifier drives it lower.

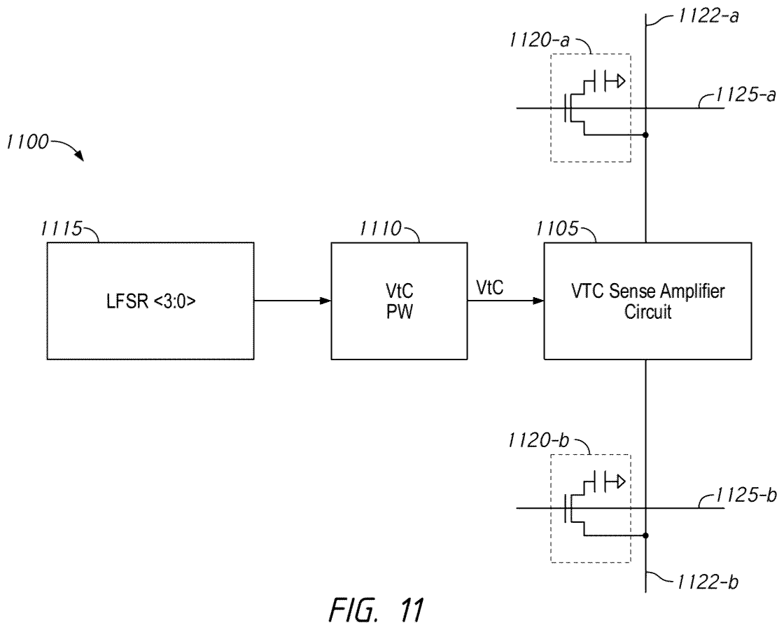

FIG. 11 illustrates a memory system in accordance with an embodiment of the present disclosure. FIG. 11 may generally depict the embodiments relating to FIGS. 4-6, and the embodiments relating to FIGS. 7-10, combined together. That is, both degrees of randomness or pseudo-randomness are combined to achieve a highly random initialization of counter memory cells, making it difficult for malicious users to take advantage of the memory system for row hammer, waterfall, or cascade attacks. In some examples, VtC sense amplifier 1105 may include VtC sense amplifier 800.

For brevity, the embodiments of FIGS. 4-6 and FIGS. 7-10 will not be recited again. Generally, the VtC sense amplifier 1105 senses residual charge on complementary memory cells 1120-a and 1120-b that are coupled to respective digit lines 1122-a and 1122-b when word lines 1125-a and 1125-b are activated, and amplifies these charges depending on which charge is greater. The memory cells 1120-a and 1120-b may be counter memory cells in some embodiments of the disclosure. Which residual charge will be greater is essentially random.

Further, the VtC sense amplifier 1105 receives a pulse width signal from VtC pulse width generator 1110. VtC pulse width generator 1110 generates a pulse width signal based on a pseudo-random generator, such as LFSR circuit 1115. This adds a second layer of randomness to generating random values for counter memory cells 1120-a and 1120-b.

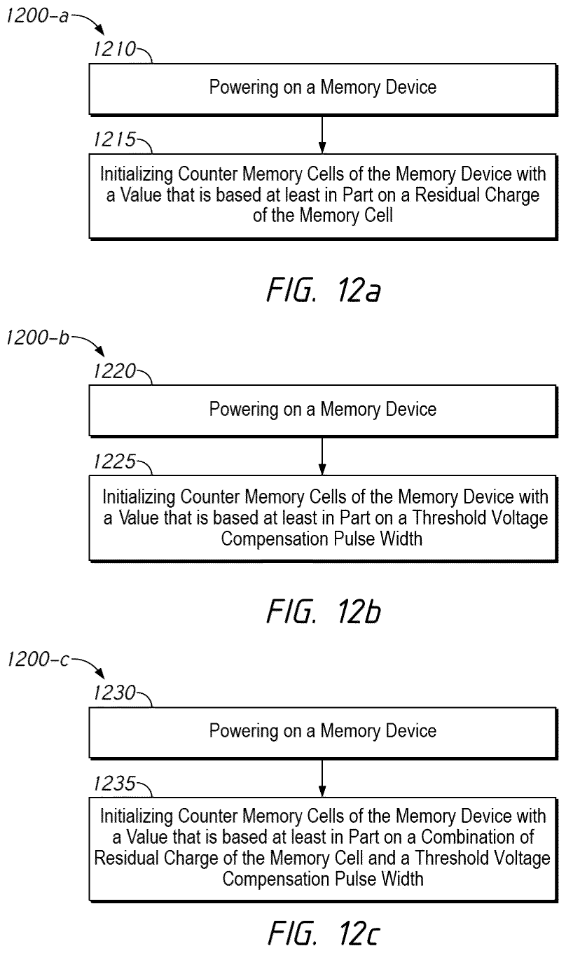

FIGS. 12a-12e are flowcharts depicting methods of initializing counter memory cells according to some embodiments of the present disclosure. Although methods 1200-a, 1200-b, and 1200-c are described with respect to certain steps (e.g., as described in blocks 1210-1215, 1220-1225, and 1230-1235) it will be appreciated that more or fewer steps may be used in other embodiments, or that steps may be repeated and/or performed in different orders.

With reference to FIG. 12a, block 1210 describes powering on a memory device. In some cases, a memory cell (e.g., 510-a, 510-b, 1120-a, 1120-b) may include a capacitor that is storing a residual charge (e.g., before powering on or start-up).

Block 1215 describes initializing counter memory cells of the memory device with a value that is based at least in part on a residual charge of a memory cell (e.g., a counter memory cell and/or another memory cell). In some examples, block 1215 may include amplifying the residual charge (e.g., using a sense amplifier such as sense amplifier 505 or 800) and writing the state of the amplified residual charge to the counter memory cell. In some examples, the first residual charge may be from before start-up of the volatile memory device.

With reference to FIG. 12b, block 1220 describes powering on a memory device. Block 1225 may include modifying the threshold voltage compensation pulse width. The resulting state of a memory cell (e.g., a counter memory cell and/or another memory cell) determined by the sense amplifier operation including the modified threshold voltage compensation pulse width may be written to the counter memory cell. In some embodiments, the VtC compensation pulse width may be based at least in part on a pseudo-random generator circuit (e.g., LFSR).

With reference to FIG. 12c, block 1230 describes powering on a memory device. Block 1235 describes initializing counter memory cells of the memory device with a value that is based at least in part on a combination of a residual charge of a memory cell (e.g., a counter memory cell and/or another memory cell) and modifying the threshold voltage compensation pulse width. The resulting state determined by a sense amplifier operation relying on the residual charge of the memory cell (and/or another memory cell) and a modified threshold voltage compensation pulse width may be written to the counter memory cells.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus, comprising:
a first digit line;
a first word line; and
a first memory cell coupled to the first digit line and to the first word line, wherein the first memory cell is configured to store a first value, and wherein the first value is generated based at least in part on a first residual charge in the first memory cell.

2. The apparatus of claim 1, wherein the first residual charge is from before start-up of the apparatus.

3. The apparatus of claim 1, wherein the first value is at least partially representative of an initial count value of access operations performed on a row of memory cells.

4. The apparatus of claim 1, further comprising:
a sense amplifier, wherein the first value is generated based at least in part on operations by the sense amplifier on the first residual charge.

5. The apparatus of claim 4, wherein the sense amplifier comprises a threshold voltage compensation sense amplifier, the apparatus further comprising:
a pseudo-random generator circuit configured to generate a value having a plurality of bits; and
a threshold voltage compensation pulse width generator circuit configured to generate a pulse width signal based at least in part on the value from the pseudo-random generator circuit, and configured to provide the pulse width signal to the sense amplifier, wherein a duration of a threshold voltage compensation phase of the sense amplifier is based at least in part on the pulse width signal.

6. The apparatus of claim 5, wherein the pseudo-random generator circuit comprises a linear feedback shift register.

7. The apparatus of claim 4, further comprising:
a second digit line coupled to the sense amplifier;
a second word line;
a second memory cell coupled to the second digit line and to the second word line, wherein the second memory cell is configured to store a second value, wherein the second value is complementary to the first value.

8. The apparatus of claim 7, wherein the sense amplifier is configured to compare the first residual charge to a second residual charge on the second memory cell.

9. An apparatus, comprising:
a first digit line;
a first word line;
a threshold voltage compensation sense amplifier coupled to the first digit line; and
a first memory cell coupled to the first digit line and to the first word line, wherein the first memory cell is configured to store a first value that is based at least in part on a random or pseudo-random threshold voltage compensation pulse width.

10. The apparatus of claim 9, wherein the first value is at least partially representative of a count of access operations performed on a row of memory cells.

11. The apparatus of claim 9, wherein the first value is generated based at least in part on a first residual charge in the first memory cell.

12. The apparatus of claim 11, wherein the first residual charge is from before start-up of the apparatus.

13. The apparatus of claim 11, further comprising:
a second digit line;
a second word line, wherein the sense amplifier is coupled to the second digit line;
a second memory cell coupled to the second digit line and to the second word line, wherein the second memory cell is configured to store a second value, wherein the second value is complementary to the first value.

14. The apparatus of claim 13, wherein the threshold voltage compensation sense amplifier is configured to compare the first residual charge to a second residual charge on the second memory cell.

15. The apparatus of claim 9, the apparatus further comprising:
a pseudo-random generator circuit configured to generate a value having a plurality of bits; and
a threshold voltage compensation pulse width generator circuit configured to generate, based at least in part on the value, a pulse width signal indicative of the threshold voltage compensation pulse width, and configured to provide the pulse width signal to the threshold voltage compensation sense amplifier, wherein a duration of a threshold voltage compensation phase of the threshold voltage compensation sense amplifier is based at least in part on the pulse width signal.

16. The apparatus of claim 15, wherein the pseudo-random generator circuit comprises a linear feedback shift register.

17. A method for initializing a counter memory cell of a memory device, comprising:
powering on the memory device; and
initializing the counter memory cell of the memory device with a value that is based at least in part on a residual charge of the counter memory cell.

18. The method of claim 17, further comprising:
amplifying the residual charge and writing the amplified residual charge to the counter memory cell.

19. A method for initializing a counter memory cell of a memory device, comprising:
powering on the a memory device; and
initializing the counter a memory cell of the memory device with a value that is based at least in part on a random or pseudo-random threshold voltage compensation pulse width for a threshold voltage compensation sense amplifier.

20. The method of claim 19, further comprising:
modifying the threshold voltage compensation pulse width based at least in part on a pseudo-random generator circuit.
